(19) United States
(12) Patent Application Publication
(10) Pub. No.: US 2022/0231146 A1
(43) Pub. Date: Jul. 21, 2022

(54) MANUFACTURING METHOD OF SEMICONDUCTOR STRUCTURE, SEMICONDUCTOR STRUCTURE, TRANSISTOR, AND MEMORY

(71) Applicant: CHANGXIN MEMORY TECHNOLOGIES, INC., Hefei City (CN)

(72) Inventor: Xiaobo MEI, Hefei City (CN)

(73) Assignee: CHANGXIN MEMORY TECHNOLOGIES, INC., Hefei City (CN)

(21) Appl. No.: 17/453,854

(22) Filed: Nov. 7, 2021

Related U.S. Application Data
(63) Continuation of application No. PCT/CN2021/109340, filed on Jul. 29, 2021.

(30) Foreign Application Priority Data
Jan. 19, 2021 (CN) 202110069755.7

(51) Int. Cl. H01L 29/45; H01L 29/40

(52) U.S. Cl. CPC H01L 29/456; H01L 29/401

(57) ABSTRACT

A manufacturing method of the semiconductor structure includes: providing a semiconductor substrate, and forming a gate region and a source-drain region on the semiconductor substrate; forming an insulating dielectric layer which covers both of the gate region and the source-drain region; patterning the insulating dielectric layer on the source-drain region to form a first contact hole exposing the source-drain region; forming a metal silicide at the bottom of the first contact hole; patterning the insulating dielectric layer on the gate region to form a second contact hole of which an orthographic projection on the semiconductor substrate is located on the gate region; and forming a filling layer in the first contact hole and the second contact hole.

### CROSS-REFERENCE TO RELATED APPLICATIONS

This is a continuation of International Application No. PCT/CN2021/109340 filed on Jul. 29, 2021, which claims priority to the Chinese Patent Application No. 202110069755.7 filed on Jan. 19, 2021. The disclosures of the above-referenced applications are hereby incorporated by reference in their entirety.

### BACKGROUND

A dynamic random-access memory (DRAM) is a semiconductor memory device commonly used in a computer, and consists of many repeated memory cells. Each memory cell usually includes a capacitor and a transistor.

It should be noted that the information disclosed in the background section above is only used to enhance the understanding of the background of the disclosure, and therefore may include information that does not constitute the prior art known to a person of ordinary skill in the art.

### SUMMARY

The disclosure relates to the technical field of storage, and in particular to a manufacturing method of a semiconductor structure, a semiconductor structure, a transistor, and a memory.

An objective of the disclosure is to provide a manufacturing method of a semiconductor structure, a semiconductor structure, a transistor and a memory.

According to an aspect of the disclosure, a manufacturing method of a semiconductor structure is provided, which includes the following operations.

A semiconductor substrate is provided, and a gate region and a source-drain region are formed on the semiconductor substrate.

An insulating dielectric layer is formed, which covers both of the gate region and the source-drain region.

The insulating dielectric layer on the source-drain region is patterned to form a first contact hole exposing the source-drain region.

A metal silicide is formed at the bottom of the first contact hole.

The insulating dielectric layer on the gate region is patterned to form a second contact hole of which an orthographic projection on the semiconductor substrate is located in the gate region.

A filling layer is formed in the first contact hole and the second contact hole.

According to another aspect of the disclosure, a semiconductor structure including a semiconductor substrate, an insulating dielectric layer, a metal silicide and a filling layer is provided.

A gate region and a source-drain region are provided on the semiconductor substrate.

The insulating dielectric layer covers both of the gate region and the source-drain region, in which, a first contact hole exposing the source-drain region and a second contact hole of which an orthographic projection on the semiconductor substrate is located in the gate region are provided on the insulating dielectric layer.

The metal silicide is formed at the bottom of the first contact hole.

The filling layer is formed in the first contact hole and the second contact hole.

According to still another aspect of the disclosure, a transistor manufactured by the above-mentioned manufacturing method is provided.

According to yet still another aspect of the disclosure, a memory including the above-mentioned transistor is provided.

It should be understood that the general description above and the following detailed description are only exemplary and illustrative, and cannot limit the disclosure.

### BRIEF DESCRIPTION OF THE DRAWINGS

The accompanying drawings herein are incorporated into the specification and constitute a part of the specification, show embodiments in accordance with the disclosure, and are used to explain the principle of the disclosure together with the specification. Apparently, the accompanying drawings in the following description are merely some embodiments of the disclosure. For a person of ordinary skilled in the art, other drawings can be obtained based on these drawings without creative work.

FIG. 1 is a flow chart of a manufacturing method of a semiconductor structure provided by an embodiment of the disclosure;

FIG. 2 is a first process diagram of manufacturing of a semiconductor structure provided by an embodiment of the disclosure;

FIG. 3 is a second process diagram of manufacturing of a semiconductor structure provided by an embodiment of the disclosure;

FIG. 4 is a third process diagram of manufacturing of a semiconductor structure provided by an embodiment of the disclosure;

FIG. 5 is a fourth process diagram of manufacturing of a semiconductor structure provided by an embodiment of the disclosure;

FIG. 6 is a fifth process diagram of manufacturing of a semiconductor structure provided by an embodiment of the disclosure;

FIG. 7 is a sixth process diagram of manufacturing of a semiconductor structure provided by an embodiment of the disclosure;

FIG. 8 is a seventh process diagram of manufacturing of a semiconductor structure provided by an embodiment of the disclosure;

FIG. 9 is a schematic diagram of a semiconductor structure provided by an embodiment of the disclosure; and

FIG. 10 is a comparison diagram of the degree of etching and removal of the material, tungsten, in an existing manufacturing method and the degree of etching and removal of the material, tungsten, in a manufacturing method provided by an embodiment of the disclosure.

### DETAILED DESCRIPTION

Exemplary implementations will be now described more comprehensively with reference to the accompanying drawings. However, the example implementations can be implemented in various forms, and should not be construed as being limited to the implementations set forth herein. On the contrary, these implementations are provided to make the disclosure comprehensive and complete, and the concept of the example implementations is fully conveyed to those skilled in the art. The same reference numerals in the drawings indicate the same or similar structures, and thus the detailed descriptions thereof are omitted.

Although relative terms, such as “upper” and “lower”, are used in the specification to describe the relative relationship between one component and another component signed in the drawings, these terms are used in the specification only for convenience, for example, the directions according to the examples described in the drawings. It can be understood that if a device signed in the drawings is turned over and inverted, the “upper” component will become the “lower” component. When a structure is located “on” another structure, it may mean that the structure is integrally formed on another structure, or the structure is “directly” disposed on said another structure, or the structure is “indirectly” disposed on said another structure through another structure.

The terms “a”, “an”, “the”, and “said” are used to indicate the presence of one or more elements/components/etc. The terms “including” and “having” are used in an open-type inclusive sense and mean that there may be additional elements/components/etc. except the listed elements/components/etc. The terms “first” and “second” are used merely as labels and are not to limit the number of objects.

In a modern integrated circuit manufacturing process, chips are subjected to a series of processes such as cleaning, film formation, etching, and heat treatment. Each process may introduce various defects. The cost of loss caused by device defects is extremely expensive.

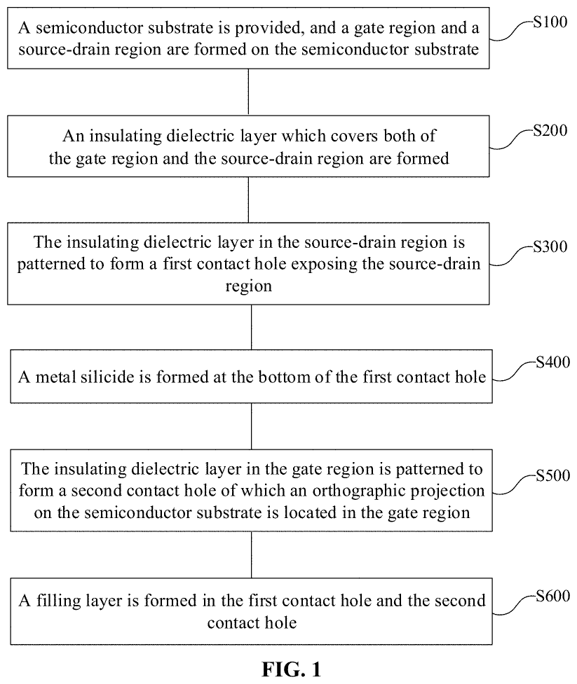

An embodiment of disclosure first provides a manufacturing method of a semiconductor structure. As shown in FIG. 1, the manufacturing method of a semiconductor structure includes the following operations.

At S100, a semiconductor substrate is provided, and a gate region and a source-drain region are formed on the semiconductor substrate.

At S200, an insulating dielectric layer is formed, which covers both of the gate region and the source-drain region.

At S300, the insulating dielectric layer on the source-drain region is patterned to form a first contact hole exposing the source-drain region.

At S400, metal silicide is formed at the bottom of the first contact hole.

At S500, the insulating dielectric layer on the gate region is patterned to form a second contact hole of which an orthographic projection on the semiconductor substrate is located on the gate region.

At S600, a filling layer is formed in the first contact hole and the second contact hole.

According to the manufacturing method of a semiconductor structure provided by the disclosure, firstly, the first contact hole exposing the source-drain region is formed. Then metal silicide is formed in the first contact hole. After the metal silicide is formed, a mask is used to form the second contact hole of which an orthographic projection is located on the gate region, so as to prevent the metal silicide from being formed in the second contact hole at the same time. Since no metal silicide is formed in the second contact hole, it is not necessary to perform an operation of removing metal silicide in the second contact hole. Thus, the conductive material at the bottom of the second contact hole is avoided to be removed, thereby avoiding the defects introduced by the process, and improving the performance and the product yield of the semiconductor structure.

Hereinafter, each operation in the manufacturing method of a semiconductor structure provided by the disclosure will be described in detail.

At S100, a semiconductor substrate is provided, and a gate region and a source-drain region are formed on the semiconductor substrate.

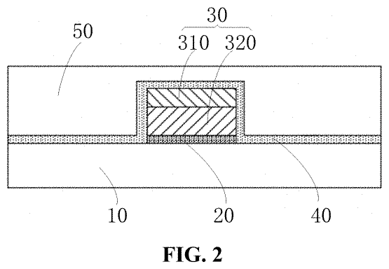

Specifically, as shown in FIG. 2, the semiconductor substrate may be formed by physical vapor deposition (PVD), chemical vapor deposition (CVD), spin coating, or a combination thereof. The material forming the semiconductor substrate may be, for example, amorphous silicon, polysilicon, microcrystalline silicon, single crystal silicon, oxide semiconductor materials, organic silicon materials, organic oxide semiconductor materials, or a combination thereof. The gate region and the source-drain region are pre-formed on the semiconductor substrate.

At S200, an insulating dielectric layer is formed, which covers the gate region and the source-drain region at the same time.

Specifically, as shown in FIG. 2, a gate insulating layer may be formed on one side of the semiconductor substrate by physical vapor deposition, chemical vapor deposition, spin coating, or a combination thereof. The material for forming the gate insulating layer may be, for example, silicon oxide, silicon oxynitride, silicon nitride or other suitable insulating substances, or a combination of the above-mentioned materials. The insulating material may be, for example, an organic polymer compound.

Further, as shown in FIG. 2, a gate 30 may be formed on the side of the gate insulating layer 20 away from the semiconductor substrate 10 by physical vapor deposition, chemical vapor deposition, spin coating, or a combination thereof.

For example, as shown in FIG. 2, the gate 30 includes a first conductive layer 320 and a second conductive layer 310. The first conductive layer 320 may be formed on the side of the gate insulating layer 20 away from the semiconductor substrate 10. The second conductive layer 310 may be formed on the side of the first conductive layer 320 away from the semiconductor substrate 10. In addition, the gate 30 may also include more conductive layers, which is not limited in the disclosure.

The material of the gate 30 is a conductive material. The conductive material is, for example, a metal, a conductive metal oxide, a conductive polymer, a conductive composite material, or a combination thereof. The metal may be, for example, platinum, gold, silver, aluminum, chromium, nickel, copper, molybdenum, titanium, magnesium, calcium, barium, sodium, palladium, iron, manganese, or a combination thereof. The conductive metal oxide may be, for example, indium dioxide, tin dioxide, indium tin oxide, fluorine-doped tin oxide, aluminum-doped zinc oxide, gallium-doped zinc oxide, or a combination thereof. The conductive polymer may be, for example, polyaniline, polypyrrole, polythiophene, polyacetylene, or a combination thereof. The conductive composite material may be, for example, a conductive composite material with carbon black, graphite powder, metal particles or the like dispersed. The first conductive layer 320 may be formed from an exemplary metal material above, and the second conductive layer 310 may be formed from the metal material of tungsten. In addition, the second conductive layer 310 may be a composite layer, the side of which away from the semiconductor substrate 10 may be an alloy material containing tungsten, and the side close to the semiconductor substrate 10 may be formed from a tungsten material.

Specifically, as shown in FIG. 2, an insulating dielectric layer 40 may be formed on one side of the semiconductor substrate 10 by physical vapor deposition, chemical vapor deposition, spin coating, or a combination thereof. The material for forming the insulating dielectric layer 40 may be, for example, silicon oxide, silicon oxynitride, silicon nitride or other suitable insulating materials, or a combination of the above-mentioned materials. The insulating material may be, for example, an organic polymer compound. The insulating dielectric layer 40 can be used as an etching stop layer to prevent over-etching.

The insulating dielectric layer 40 may be formed from the same material as the gate insulating layer 20, for example, both are formed from a silicon oxide material, which can reduce the process cost and improve the production efficiency.

At S300, the insulating dielectric layer in the source-drain region is patterned to form a first contact hole exposing the source-drain region.

Specifically, as shown in FIG. 2, a dielectric layer 50 may be formed on the side of the insulating dielectric layer 40 away from the semiconductor substrate 10 by physical vapor deposition, chemical vapor deposition, spin coating, or a combination thereof. The material for forming the dielectric layer 50 may be, for example, silicon oxide, silicon oxynitride, silicon nitride, organic materials, or a combination thereof.

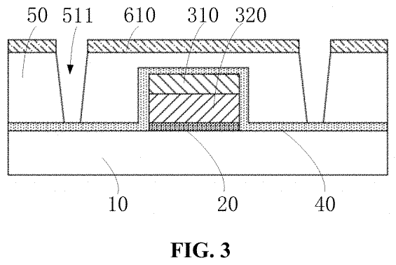

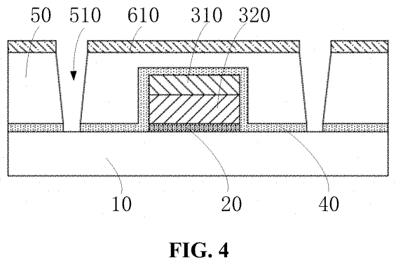

Moreover, as shown in FIG. 3, a first photoresist layer 610 may be formed on the side of the dielectric layer 50 away from the semiconductor substrate 10 by physical vapor deposition, chemical vapor deposition, spin coating, or a combination thereof. Next, a source-drain etch hole is formed by exposure and development. Then the dielectric layer 50 is etched by a first etching process through the source-drain etch hole. With the insulating dielectric layer 40 as an etching stop layer, a first via hole 511 is formed in the dielectric layer 50. As shown in FIG. 4, then it is continued to etch off the insulating dielectric layer 40 at the bottom of the first via hole 511 by using a second etching process through the source-drain etch hole, so as to form a first contact hole 510, such that the semiconductor substrate 10 is exposed from the first contact hole 510.

At S400, a metal silicide is formed at the bottom of the first contact hole.

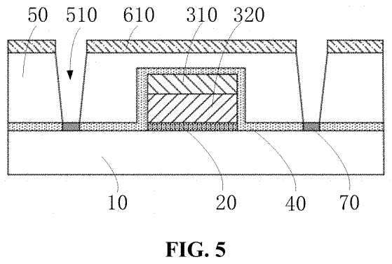

Specifically, as shown in FIG. 5, a preset metal material may be formed on the semiconductor substrate 10 in the first contact hole 510 by ink-jet printing, deposition or the like. Then heat treatment is performed, such that the preset metal material at the bottom of the first contact hole 510 reacts with silicon of the semiconductor substrate 10 to form the metal silicide 70. The material of the preset metal material may be, for example, cobalt, platinum, gold, silver, aluminum, chromium, nickel, copper, molybdenum, titanium, magnesium, calcium, barium, sodium, palladium, iron, manganese, or a combination thereof. The region of the semiconductor substrate 10 corresponding to the metal silicide 70 is an active region.

After the metal silicide 70 is formed, the part of the preset metal material that does not react with silicon of the semiconductor substrate 10 to form the metal silicide can be removed by etching or grinding. For example, after forming the first contact hole 510 and before forming the metal silicide 70, the manufacturing method further includes: forming a polysilicon layer at the bottom of the first contact hole 510, and forming a metal layer on the polysilicon layer.

Specifically, after the first contact hole 510 is formed, the polysilicon layer and the metal layer may be grown on a sidewall and the bottom of the first contact hole 510 successively. As miniaturization of the size, a gate is smaller, and the window for etching a first contact hole 510 becomes smaller, resulting in an increase in an aspect ratio of the first contact hole 510. On the one hand, a contact hole with a high aspect ratio will increase the contact resistance, which is not conducive to improvement of the electrical performance of the device. On the other hand, due to the smaller etching window, if the etching is not sufficient, the substrate will not be effectively exposed, and accordingly it is hard to avoid over-etching during etching, which will cause more silicon loss of the substrate, thereby further leading to more silicone loss to a source-drain region of the substrate when the contact hole with a high aspect ratio is etched. On the one hand, the polysilicon in the disclosure can make up for the loss of silicon in the source-drain region of the semiconductor substrate 10. On the other hand, the metal silicide 70 may also be formed on the sidewall of the first contact hole 510. Since the polysilicon and metal will react to form a metal silicide under high-temperature annealing, the metal silicide has a lower contact resistance, thus the electrical performance of the contact hole can be improved.

The annealing temperature is 600° C. to 900° C., preferably 650° C. to 850° C. The annealing duration is 20 seconds to 50 seconds.

The thickness of the polysilicon layer is 0.1 nm-5 nm, and the type of doped ions of the polysilicon layer may be the same as that of the source-drain region. The thickness of the metal layer is 1 nm-10 nm.

For example, after the metal silicide 70 is formed at the bottom of the first contact hole 510, the manufacturing method further includes: forming an adhesive barrier layer on the surface of the metal silicide 70.

Specifically, the material of the adhesive barrier layer may be, for example, one of Ti, Ta, TiN, and TaN. The adhesive barrier layer can increase the adhesion between a filling layer subsequently formed and the surface of metal silicide 70 and the adhesion between the filling layer and the inner wall of the first contact hole 510, thereby improving the formation quality of a metal plug. On the other hand, it can also prevent a reactant used when depositing the metal of the filling layer from reacting with the metal silicide 70 at the bottom of the first contact hole 510.

At S500, the insulating dielectric layer on the gate region is patterned to form a second contact hole of which an orthographic projection on the semiconductor substrate is located on the gate region.

Specifically, before patterning the insulating dielectric layer in the gate region to form the second contact hole exposing the gate region, the manufacturing method further includes: forming a sacrificial filling layer in the first contact hole 510.

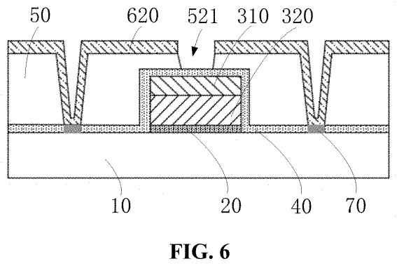

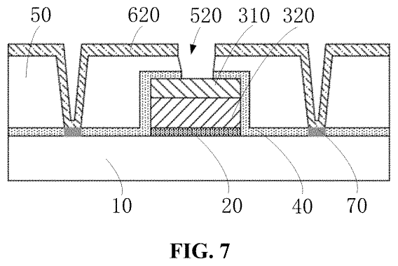

Specifically, as shown in FIG. 6, after the metal silicide 70 is formed, the first photoresist layer 610 can be removed, and a second photoresist layer 620 is formed on the side of the dielectric layer 50 away from the semiconductor substrate 10. The second photoresist layer 620 covers the first contact hole 510 and the metal silicide 70, and the second photoresist layer 620 can be used as a sacrificial filling layer. Then the second photoresist layer 620 is exposed and developed to form a gate etching hole in the second photoresist layer 620. Then through the gate etching hole, a second via hole 521 is formed in the dielectric layer 50 by using a third etching process with the insulating dielectric layer 40 used as an etching stop layer. As shown in FIG. 7, through the second via hole 521, the insulating dielectric layer 40 at the bottom of the second via hole 521 is etched off by using a fourth etching process, such that the gate 30 is exposed from the second via hole 521, thereby forming the second contact hole 520. That is, an orthographic projection of the second contact hole 520 on the semiconductor substrate 10 is located in the gate region.

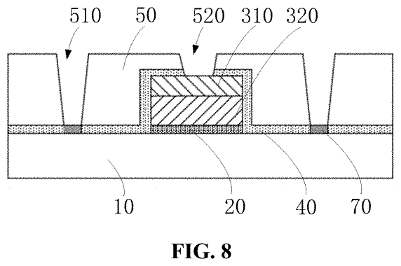

Next, as shown in FIG. 8, after the second contact hole 520 is formed, the second photoresist layer 620 is removed, such that the metal silicide 70 or the adhesive barrier layer in the first contact hole 510 is exposed.

At S600, the filling layer is formed in the first contact hole and the second contact hole.

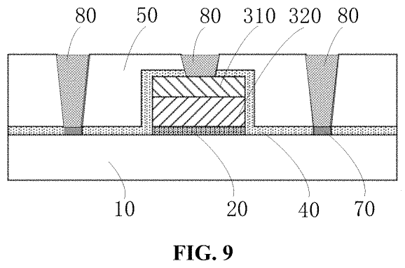

Specifically, as shown in FIG. 9, filling layers 80 may be formed in the first contact hole and the second contact hole by physical vapor deposition, chemical vapor deposition, spin coating, or a combination thereof, and the filling layers 80 may be used as conductive plugs for a source-drain and a gate respectively.

The material of the filling layer 80 is a conductive material. The conductive material is, for example, a metal, a conductive metal oxide, a conductive polymer, a conductive composite material, or a combination thereof. The metal may be, for example, platinum, gold, silver, aluminum, chromium, nickel, copper, molybdenum, titanium, magnesium, calcium, barium, sodium, palladium, iron, manganese, or a combination thereof. The conductive metal oxide may be, for example, indium dioxide, tin dioxide, indium tin oxide, fluorine-doped tin oxide, aluminum-doped zinc oxide, gallium-doped zinc oxide, or a combination thereof. The conductive polymer may be, for example, polyaniline, polypyrrole, polythiophene, polyacetylene, or a combination thereof. The conductive composite material may be, for example, a conductive composite material with carbon black, graphite powder, metal particles or the like dispersed.

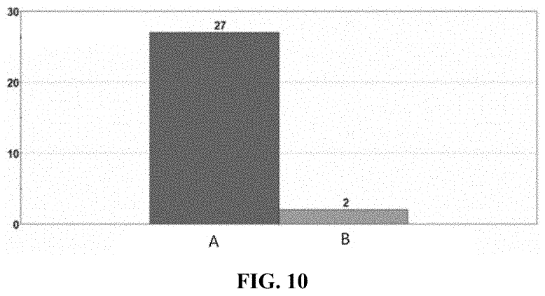

As shown in FIG. 10, A represents the degree of etching and removal of material tungsten with an existing manufacturing method, and B represents the degree of etching and removal of material tungsten in the manufacturing method provided by the embodiment of the disclosure. It can be obviously seen that according to the above-mentioned manufacturing method of the disclosure, the first contact hole 510 is formed first, then the metal silicide 70 is formed in the first contact hole 510, and after the metal silicide 70 is formed, the second contact hole 520 is formed by again using a mask, so as to prevent a metal material (such as material cobalt) from being formed in the second contact hole 520 at the same time when forming the metal silicide, thereby avoiding removing part of material tungsten on the surface of the gate 30 when removing unreacted metal (such as material cobalt) in the second contact hole 520, such that the performance of the transistor is improved.

The first photoresist layer 610 can be formed with the same method and material as the second photoresist layer 620. The first etching process, the second etching process, the third etching process, and the fourth etching process are only names of the etching processes in different sequences. The first etching process, the second etching process, the third etching process, and the fourth etching process may be the same etching process or different processes. The specific etching process is a conventional etching process in the art, and the descriptions thereof are omitted here.

It should be noted that although each step of the method in the disclosure is described in a specific order in the drawings, it does not require or suggest that these steps must be performed in this specific order, or that all the steps shown must be performed to achieve the desired results. Additionally or alternatively, some steps may be omitted, multiple steps may be combined into one step for execution, and/or one step may be divided into multiple steps for execution, etc.

An embodiment of the disclosure further provides a semiconductor structure. As shown in FIG. 9, the semiconductor structure includes a semiconductor substrate 10, an insulating dielectric layer 40, a metal silicide 70, and a filling layer 80. A gate region and a source-drain region are formed on the semiconductor substrate 10. The insulating dielectric layer 70 covers both of the gate region and the source-drain region. A first contact hole 510 exposing the source-drain region and a second contact hole 520 exposing the gate region are formed on the insulating dielectric layer 70. The metal silicide 70 is formed at the bottom of the first contact hole 510. The filling layer 80 is formed in the first contact hole 510 and the second contact hole 520.

According to the semiconductor structure provided by the disclosure, the first contact hole exposing the source-drain region is formed. The metal silicide is formed in the first contact hole, but not formed in the second contact hole, so as to avoid part of a conductive material at the bottom of the second contact hole being removed, thereby avoiding the defects introduced by process, and improving the performance and the product yield of the semiconductor structure.

Specifically, the metal silicide 70 is also formed on the sidewall of the first contact hole 510. A preset metal material may be formed on the semiconductor substrate 10 in the first contact hole 510 by ink-jet printing, deposition or the like. Then heat treatment is performed, such that the preset metal material at the bottom of the first contact hole 510 reacts with silicon on the semiconductor substrate 10 to form the metal silicide 70. By forming the metal silicide 70 on the sidewall of the first contact hole 510, the electrical performance of the contact hole can be further improved.

Specifically, the semiconductor structure further includes an adhesive barrier layer formed on the surface of the metal silicide 70 away from the semiconductor substrate 10. Herein, the material of the adhesive barrier layer may be, for example, one of Ti, Ta, TiN, and TaN. The adhesive barrier layer can increase the adhesion between the subsequent filling layer and the surface of metal silicide 70 and the adhesion between the filling layer and an inner wall of the first contact hole 510, thereby improving the formation quality of a metal plug. On the other hand, it can also prevent a reactant used when depositing the metal of the filling layer from reacting with the metal silicide 70 at the bottom of the first contact hole 510.

Since the semiconductor structure of the exemplary embodiment of the disclosure corresponds to the steps of the exemplary embodiment of the above-mentioned semiconductor structure manufacturing method, for details that are not disclosed in the structural embodiment of the disclosure, please refer to the above-mentioned embodiment of the semiconductor structure manufacturing method of the disclosure.

The disclosure further provides a transistor, manufactured by the above-mentioned manufacturing method. For the beneficial effects of the transistor, reference can be made to the description of the beneficial effects of the manufacturing method above, and the description is omitted here. The transistor may be a metal oxide semiconductor (MOS, metal oxide semiconductor field effect) transistor. Of course, it may also be a thin film transistor (TFT), and the types thereof are not specifically limited here.

The disclosure further provides a memory including the above-mentioned transistor. The memory may be a dynamic random-access memory (DRAM). Of course, it may also be a read-only memory (ROM), and the types thereof are not specifically limited here. The memory can be used in mobile phones, tablet computers or other terminal devices. For the beneficial effects thereof, reference can be made to the description of the beneficial effects of the manufacturing method above, and the description is omitted here.

After considering the specification and implementing the disclosure disclosed herein, other implementation solutions of the disclosure would readily be conceivable to those skilled in the art. This application is intended to cover any variations, uses, or adaptive changes of the disclosure. These variations, uses, or adaptive changes follow the general principles of the disclosure and include common general knowledge or conventional technical means in the art, which are not disclosed herein. The specification and the embodiments are considered as being exemplary only, with a true scope and spirit of the disclosure being indicated by the following claims.

It should be understood that the disclosure is not limited to the exact construction that has been described above and illustrated in the accompanying drawings, and that various modifications and changes may be made without departing from the scope thereof. It is intended that the scope of the disclosure only be limited by the appended claims.

What is claimed is:

1. A manufacturing method of a semiconductor structure, comprising:
providing a semiconductor substrate, and forming a gate region and a source-drain region on the semiconductor substrate;
forming an insulating dielectric layer which covers both of the gate region and the source-drain region;
patterning the insulating dielectric layer on the source-drain region to form a first contact hole exposing the source-drain region;
forming a metal silicide at the bottom of the first contact hole;
patterning the insulating dielectric layer on the gate region to form a second contact hole of which an orthographic projection on the semiconductor substrate is located on the gate region; and
forming a filling layer in the first contact hole and the second contact hole.

2. The manufacturing method of claim 1, wherein, patterning the insulating dielectric layer on the source-drain region to form the first contact hole exposing the source-drain region comprises:
forming a photoresist layer on the side of the insulating dielectric layer away from the semiconductor substrate;
forming a first contact hole pattern on the photoresist layer; and
etching the insulating dielectric layer through the first contact hole pattern until the semiconductor substrate is exposed.

3. The manufacturing method of claim 1, wherein, forming the metal silicide at the bottom of the first contact hole comprises:
depositing a preset metal material at the bottom of the first contact hole; and
performing heat treatment to the preset metal material, such that the preset metal material reacts with silicon in the semiconductor substrate to form the metal silicide.

4. The manufacturing method of claim 3, further comprising: after forming the metal silicide at the bottom of the first contact hole,
removing the preset metal material that does not react with silicon in the semiconductor substrate to form the metal silicide.

5. The manufacturing method of claim 1, further comprising: before patterning the insulating dielectric layer on the gate region to form the second contact hole of which the orthographic projection on the semiconductor substrate is located in the gate region,
forming a sacrificial filling layer in the first contact hole.

6. The manufacturing method of claim 5, further comprising: after forming the second contact hole and before forming the filling layer,
removing the sacrificial filling layer.

7. The manufacturing method of claim 1, further comprising: after forming the first contact hole, and before forming the metal silicide,
forming a polysilicon layer at the bottom of the first contact hole; and
forming a metal layer on the polysilicon layer.

8. The manufacturing method of claim 7, wherein:
the polysilicon layer is further formed on a sidewall of the first contact hole; and
the metal layer is further formed on the surface of the polysilicon layer on the sidewall.

9. The manufacturing method of claim 1, further comprising: after forming the metal silicide at the bottom of the first contact hole,
forming an adhesive barrier layer on the surface of the metal silicide.

10. A semiconductor structure, comprising:
a semiconductor substrate, with a gate region and a source-drain region located thereon;
an insulating dielectric layer, covering both of the gate region and the source-drain region, wherein a first contact hole exposing the source-drain region and a second contact hole of which an orthographic projection on the semiconductor substrate is located in the gate region are provided on the insulating dielectric layer;
a metal silicide, located at the bottom of the first contact hole; and
a filling layer, located in the first contact hole and the second contact hole.

11. The semiconductor structure of claim 10, wherein, the metal silicide is also located on a sidewall of the first contact hole.

12. The semiconductor structure of claim 10, wherein, the semiconductor structure further comprises:
an adhesive barrier layer, located on the surface of the metal silicide away from the semiconductor substrate.

13. A transistor, comprising a semiconductor structure which is manufactured by a manufacturing method of a semiconductor structure, wherein, the manufacturing method comprises:
providing a semiconductor substrate, and forming a gate region and a source-drain region on the semiconductor substrate;
forming an insulating dielectric layer which covers both of the gate region and the source-drain region;
patterning the insulating dielectric layer on the source-drain region to form a first contact hole exposing the source-drain region;
forming a metal silicide at the bottom of the first contact hole;
patterning the insulating dielectric layer on the gate region to form a second contact hole of which an orthographic projection on the semiconductor substrate is located on the gate region; and
forming a filling layer in the first contact hole and the second contact hole.

14. The transistor of claim 13, wherein forming the metal silicide at the bottom of the first contact hole comprises:
depositing a preset metal material at the bottom of the first contact hole; and
performing heat treatment to the preset metal material, such that the preset metal material reacts with silicon in the semiconductor substrate to form the metal silicide.

15. The transistor of claim 13, wherein the manufacturing method further comprises: after forming the metal silicide at the bottom of the first contact hole,
removing the preset metal material that does not react with silicon in the semiconductor substrate to form the metal silicide.

16. The transistor of claim 13, wherein the manufacturing method further comprises: after forming the first contact hole, and before forming the metal silicide,
forming a polysilicon layer at the bottom of the first contact hole; and
forming a metal layer on the polysilicon layer.

17. A memory comprising the transistor of claim 13.

18. A memory comprising the transistor of claim 14.

19. A memory comprising the transistor of claim 15.

20. A memory comprising the transistor of claim 16.
